(19) United States
(12) Patent Application Publication
(10) Pub. No.: US 2024/0096835 A1
(43) Pub. Date: Mar. 21, 2024

(54) MANUFACTURING METHOD OF ELECTRONIC PACKAGE

(71) Applicant: SILICONWARE PRECISION INDUSTRIES CO., LTD., Taichung (TW)

(72) Inventors: Pin-Jing SU, Research Triangle Park, NC (US); Liang-Yi HUNG, Research Triangle Park, NC (US); Yu-Po WANG, Research Triangle Park, NC (US)

(73) Assignee: SILICONWARE PRECISION INDUSTRIES CO., LTD., Taichung (TW)

(21) Appl. No.: 18/055,890

(22) Filed: Nov. 16, 2022

(30) Foreign Application Priority Data
Sep. 21, 2022 (TW) 111135757

(51) Int. Cl. H01L 23/00

(52) U.S. Cl. CPC H01L 24/16; H01L 24/32; H01L 24/73; H01L 2224/02379; H01L 2224/03515; H01L 2224/17519; H01L 2224/24998; H01L 2224/33519; H01L 2224/7525; H01L 2924/16235

(57) ABSTRACT

A method of manufacturing an electronic package is provided, in which an electronic element is disposed on a carrier structure; a heat dissipation body of a heat dissipation structure is disposed on the electronic element via a heat dissipation material; the heat dissipation material is cured; supporting legs of the heat dissipation structure are fixed on the carrier structure via a bonding layer; and the bonding layer is cured. Therefore, the heat dissipation structure can be effectively fixed to the heat dissipation material and the bonding layer by completing the arrangements of the heat dissipation material and the bonding layer in stages.

### BACKGROUND

### 1. Technical Field

The present disclosure relates to a semiconductor packaging process, and more particularly, to a manufacturing method of an electronic package with a heat dissipation structure.

### 2. Description of Related Art

With the increase in demand in the function and processing speed of electronic products, the semiconductor chip, which is a core component of electronic products, needs to have higher density of electronic elements and electronic circuits, such that greater amount of heat energy is generated during the operation of the semiconductor chip. Furthermore, the conventional encapsulant for encapsulating the semiconductor chip is made from a poor heat transfer material (i.e., poor heat dissipation efficiency) with a thermal conductivity of only 0.8 W·m⁻¹·K⁻¹ (watts/[meter·Kelvin]). Therefore, if the heat generated by the semiconductor chip cannot be effectively dissipated, the heat would damage the semiconductor chip and cause product reliability problems.

Therefore, in order to quickly dissipate the heat energy to the outside, the semiconductor package is usually configured with a heat sink or a heat spreader in the industry. The heat sink is bonded to the back of the semiconductor chip usually by a heat dissipation glue (such as a thermal interface material [TIM]), so that the heat generated by the semiconductor chip can be dissipated via the heat dissipation glue and the heat sink; in addition, a top surface of the heat sink is usually exposed from the encapsulant or directly exposed to the atmosphere, so as to obtain better heat dissipation effect.

As shown in FIG. 1A to FIG. 1B, in a method of manufacturing a conventional semiconductor package 1, a semiconductor chip 11 is first disposed on a package substrate 10 by a flip-chip bonding method (i.e., via conductive bumps 110 and an underfill 111) with an active surface 11a of the semiconductor chip 11, a TIM layer 12 is then formed on an inactive surface 11b of the semiconductor chip 11, and an adhesive layer 14 is formed on the package substrate 10. Next, a heat sink 13 is bonded onto the inactive surface 11b of the semiconductor chip 11 via the TIM layer 12 with a top sheet 130 of the heat sink 13, and supporting legs 131 of the heat sink 13 are disposed on the package substrate 10 via the adhesive layer 14. After that, a baking operation is performed, as shown in FIG. 1C, to thermally solidify (e.g., cure) the TIM layer 12 and the adhesive layer 14.

During operation, the heat energy generated by the semiconductor chip 11 is conducted to the heat sink 13 via the inactive surface 11b and the TIM layer 12, so that heat is dissipated to the outside of the semiconductor package 1.

However, in the method of manufacturing the conventional semiconductor package 1, when the TIM layer 12 and the adhesive layer 14 are thermally solidified/cured by the baking operation, the stress of the semiconductor package 1 is often unevenly distributed due to the great mismatch of the coefficient of thermal expansion (CTE) between the TIM layer 12 and the adhesive layer 14, resulting in deformation (i.e., warpage) between the heat sink 13 and the TIM layer 12, and thus causing delamination d between the top sheet 130 of the heat sink 13 and the TIM layer 12, as shown in FIG. 1C, which not only causes the thermal conductivity to decrease, but also causes the poor reliability of the end product using the semiconductor package 1.

Therefore, there is a need for a solution that addresses the aforementioned shortcomings in the prior art.

### SUMMARY

In view of the aforementioned shortcomings of the prior art, the present disclosure provides a method of manufacturing an electronic package, the method comprises: disposing an electronic element on a side of a carrier structure; forming a heat dissipation material on the electronic element; bonding a heat dissipation structure on the heat dissipation material to cover the electronic element; performing a first heating operation to cure the heat dissipation material to complete an arrangement of the heat dissipation material; forming a bonding layer on the side of the carrier structure and on the heat dissipation structure after completing the first heating operation; and performing a second heating operation to cure the bonding layer to complete an arrangement of the bonding layer, wherein the heat dissipation structure is fixed on the carrier structure via the bonding layer.

In the aforementioned method, the heat dissipation material is a thermal interface material.

In the aforementioned method, the heat dissipation material is a solder material, a silicone material, or an ultraviolet glue material.

In the aforementioned method, the heat dissipation structure comprises a heat dissipation body and a plurality of supporting legs erected on the heat dissipation body, wherein the heat dissipation body is in contact with and bonded with the heat dissipation material, and the plurality of supporting legs are in contact with and bonded with the bonding layer. For example, the plurality of supporting legs are suspended on the carrier structure before forming the bonding layer.

In the aforementioned method, the bonding layer is made from a thermosetting glue material.

In the aforementioned method, a material for forming the bonding layer is different from that of the heat dissipation material.

The aforementioned method further comprises forming a plurality of conductive elements on another side of the carrier structure.

As can be understood from the above, in the method of manufacturing the electronic package according to the present disclosure, the heat dissipation material is cured first, and then the bonding layer is formed. Therefore, compared with the prior art, the manufacturing method of the present disclosure completes the arrangements of the heat dissipation material and the bonding layer in stages, so that the heat dissipation structure is effectively fixed to the heat dissipation material and the bonding layer, and thus avoiding the problem of delamination between the heat dissipation structure and the heat dissipation material.

### BRIEF DESCRIPTION OF THE DRAWINGS

FIG. 1A to FIG. 1C are schematic cross-sectional views illustrating a method of manufacturing a conventional semiconductor package.

FIG. 2A to FIG. 2C are schematic cross-sectional views illustrating a method of manufacturing an electronic package of the present disclosure.

FIG. 2D is a schematic cross-sectional view showing a subsequent process of FIG. 2C.

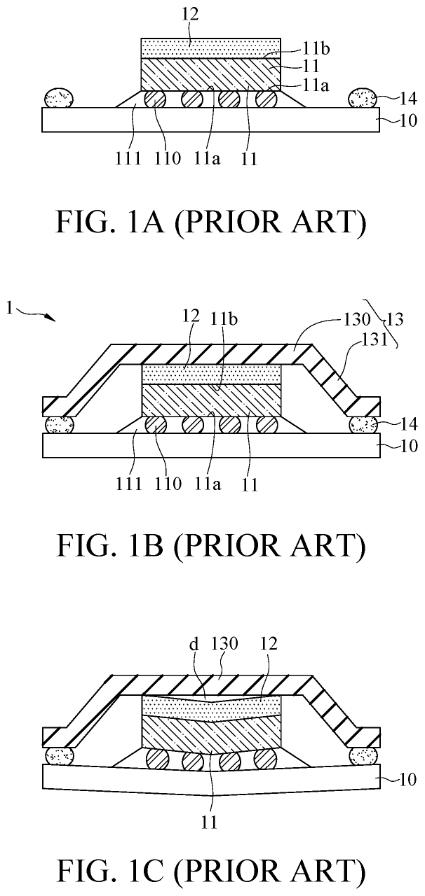

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios or sizes are construed as falling within the scope covered by the technical contents disclosed herein. Meanwhile, terms such as “on,” “above,” “below,” “first,” “second,” “one,” “a,” “an,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

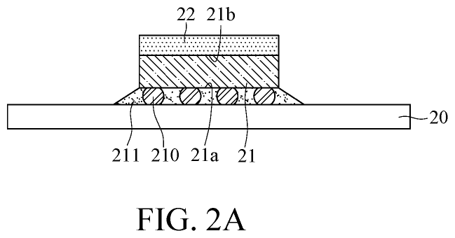

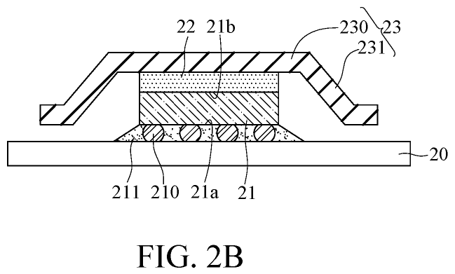

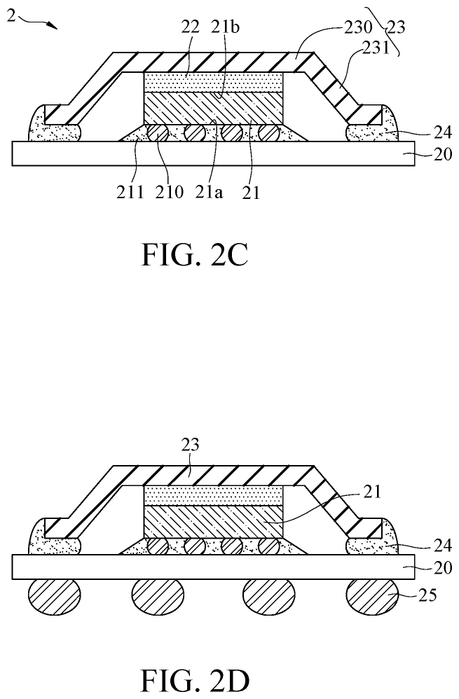

FIG. 2A to FIG. 2C are schematic cross-sectional views illustrating a method of manufacturing an electronic package 2 of the present disclosure.

As shown in FIG. 2A, at least one electronic element 21 is disposed on one side of a carrier structure 20, and a heat dissipation material 22 is formed on the electronic element 21.

In an embodiment, the carrier structure 20 is, for example, a package substrate with a core layer and a circuit structure, a package substrate with a coreless circuit structure, a through-silicon interposer (TSI) with conductive through-silicon vias (TSVs), or other types of board, wherein the carrier structure 20 comprises at least one insulating layer and at least one circuit layer (such as at least one fan-out type redistribution layer [RDL]) bonded with the insulating layer. It should be understood that the carrier structure 20 can also be other types of board for carrying chips, such as a lead frame, a wafer, or a board with metal routings, etc., and the present disclosure is not limited to as such.

Moreover, the electronic element 21 is an active element, a passive element, a chip module, or a combination thereof, wherein the active element may be a semiconductor chip, and the passive element may be a resistor, a capacitor, or an inductor. In an embodiment, the electronic element 21 is a semiconductor chip and has an active surface 21a and an inactive surface 21b opposing the active surface 21a, wherein the active surface 21a is disposed on the circuit layer of the carrier structure 20 in a flip-chip manner via a plurality of conductive bumps 210 such as solder material, metal pillars, or the like and is electrically connected to the circuit layer, and an underfill 211 is formed between the carrier structure 20 and the active surface 21a to cover the conductive bumps 210. Alternatively, the electronic element 21 can be electrically connected to the circuit layer of the carrier structure 20 via a plurality of bonding wires (not shown) in a wire-bonding manner; or, the electronic element 21 can directly contact the circuit layer of the carrier structure 20. It should be understood that there are many ways in which the electronic element 21 can be electrically connected to the carrier structure 20, and the required type and quantity of the electronic element 21 that can be disposed onto the carrier structure 20 are not limited to the above.

Furthermore, the heat dissipation material 22 is formed on the inactive surface 21b of the electronic element 21, and the heat dissipation material 22 has a high thermal conductivity of about 30-80 W·m⁻¹·K⁻¹ (watts/[meter·Kelvin]) to serve as a thermal interface material (TIM). For example, the heat dissipation material 22 is a solder material, a silicone material, an ultraviolet (UV) glue material, or other thermosetting/thermo-curing material. It should be understood that there are many types of TIM, and the present disclosure is not limited to the above.

As shown in FIG. 2B, a heat dissipation structure 23 is bonded on the heat dissipation material 22 to cover the electronic element 21, and then a first heating operation is performed to thermally solidify (e.g., cure) the heat dissipation material 22 so as to complete the arrangement of the heat dissipation material 22.

In an embodiment, the heat dissipation structure 23 comprises a sheet-shaped heat dissipation body 230 and a plurality of supporting legs 231 erected on the heat dissipation body 230, so that the heat dissipation body 230 is in contact with the heat dissipation material 22, and the supporting legs 231 are suspended on the carrier structure 20.

In addition, the heating method and temperature of the first heating operation are changed according to the type of the heat dissipation material 22. For example, if the heat dissipation material 22 is a solder material, the first heating operation is performed in a manner of reflowing.

As shown in FIG. 2C, a bonding layer 24 is formed between the carrier structure 20 and the supporting legs 231 of the heat dissipation structure 23, and a second heating operation is performed to thermally solidify (e.g., cure) the bonding layer 24, and the arrangement of the bonding layer 24 is completed, so that the heat dissipation structure 23 is fixed on the carrier structure 20 by the bonding layer 24.

In an embodiment, the bonding layer 24 is made from a thermosetting/thermo-curing glue material, so as to adhere the supporting legs 231 onto the carrier structure 20. For example, a material for forming the bonding layer 24 is different from a material for forming the heat dissipation material 22, and the CTE of the bonding layer 24 and the CTE of the heat dissipation material 22 are different accordingly. It should be understood that there are many kinds of the bonding layer 24, and the present disclosure is not limited to the above.

Moreover, the second heating operation is performed in a manner of baking. For example, the baking temperature of the second heating operation is changed based on the type of the bonding layer 24.

Accordingly, in the method of manufacturing the electronic package 2 of the present disclosure, the heat dissipation body 230 is fixed on the electronic element 21 by firstly thermosetting/curing the heat dissipation material 22, and then the supporting legs 231 are fixed onto the carrier structure 20 via the bonding layer 24. Therefore, compared with the prior art, even if the heat dissipation body 230 is deformed (i.e., warped) after the heat dissipation material 22 is baked, the stress distribution of the electronic package 2 can still be adjusted via the amount of the bonding layer 24 used, so that the bonding layer 24 not only can fix the supporting legs 231 on the carrier structure 20, but also can change the degree of warpage via the second heating operation, such that the stress distribution of the heat dissipation body 230 becomes more even, so as to effectively avoid the problem of delamination between the heat dissipation body 230 and the heat dissipation material 22.

In addition, in the subsequent process, a plurality of conductive elements 25 such as solder balls can be disposed on the other side of the carrier structure 20 (i.e., the lower part of the carrier structure 20 as shown in FIG. 2D), so that the electronic package 2 can be disposed on an electronic device such as a circuit board (not shown) via the conductive elements 25.

In view of the above, in the method of manufacturing the electronic package of the present disclosure, the arrangements of the heat dissipation material and the bonding layer are completed in stages, so that the heat dissipation structure can be effectively fixed to the heat dissipation material and the bonding layer. Therefore, the manufacturing method of the present disclosure not only can improve the heat conduction effect, but also can improve the reliability of the end product.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A method of manufacturing an electronic package, comprising:
disposing an electronic element on a side of a carrier structure;
forming a heat dissipation material on the electronic element;
bonding a heat dissipation structure on the heat dissipation material to cover the electronic element;
performing a first heating operation to cure the heat dissipation material to complete an arrangement of the heat dissipation material;
forming a bonding layer on the side of the carrier structure and on the heat dissipation structure after completing the first heating operation; and
performing a second heating operation to cure the bonding layer to complete an arrangement of the bonding layer, wherein the heat dissipation structure is fixed on the carrier structure via the bonding layer.

2. The method of claim 1, wherein the heat dissipation material is a thermal interface material.

3. The method of claim 1, wherein the heat dissipation material is a solder material.

4. The method of claim 1, wherein the heat dissipation material is a silicone material.

5. The method of claim 1, wherein the heat dissipation material is an ultraviolet glue material.

6. The method of claim 1, wherein the heat dissipation structure comprises a heat dissipation body and a plurality of supporting legs erected on the heat dissipation body, wherein the heat dissipation body is in contact with and bonded with the heat dissipation material, and the plurality of supporting legs are in contact with and bonded with the bonding layer.

7. The method of claim 6, wherein the plurality of supporting legs are suspended on the carrier structure before forming the bonding layer.

8. The method of claim 1, wherein the bonding layer is made from a thermosetting glue material.

9. The method of claim 1, wherein a material for forming the bonding layer is different from that of the heat dissipation material.

10. The method of claim 1, further comprising forming a plurality of conductive elements on another side of the carrier structure.
